(19) United States
(12) Patent Application Publication
(10) Pub. No.: US 2006/0261362 A1
(43) Pub. Date: Nov. 23, 2006

(54) LED lamp and LED lamp apparatus

(75) Inventors: Kazushi Noda, Aichi-ken (JP); Takayuki Kamiya, Aichi-ken (JP); Yoshio Sano, Aichi-ken (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: TOYODA GOSEI CO., LTD., Aichi-ken (JP)

(21) Appl. No.: 11/435,278

(22) Filed: May 17, 2006

(30) Foreign Application Priority Data
May 19, 2005 (JP) 2005-146280
Dec. 28, 2005 (JP) 2005-379514

(51) Int. Cl. H01L 33/00

(52) U.S. Cl. 257/98

(57) ABSTRACT

An LED lamp has: a sealing member; first, second and third leads, a part of the first, second and third leads being surrounded by the sealing member; an LED chip mounted on the first lead; and a wire disposed connecting the second lead and the LED chip. The third lead is connected through an electrical path to the first or second lead.

The present application is based on Japanese patent Application Nos. 2005-146280 and 2005-379514, the entire contents of which are incorporated herein by reference.

### BACKGROUND OF THE INVENTION

1. Field of the Invention

This invention relates to an LED lamp and an LED lamp apparatus using the LED lamp.

2. Description of the Related Art

JP-A-2003-258314 discloses an LED lamp apparatus. The LED lamp apparatus 101 comprises, as shown in FIG. 1, an LED lamp 102, a circuit portion 105, a terminal 107 and case portions 108, 109. The LED lamp 102 comprises a pair of leads 103, 103, and a bullet-shaped sealing member 104 surrounding the base end portion of the leads. An LED chip is embedded in the sealing member 104. The circuit portion 105 is formed of a metal plate and secured by an inner case 108, and a resistor 106 is attached to the circuit portion. 107 is a terminal connected to a control device (not shown). The resistor 106 is provided to control the amount of current supplied to the LED lamp 102.

The LED lamp apparatus 101 thus composed is inexpensive in fabrication cost since the metal plate is substituted for an expensive printed-circuit board.

JP-A-5-62059 (Utility model) also relates to the invention.

However, it is desired to simplify the construction of the LED lamp apparatus to facilitate the fabrication thereof.

### SUMMARY OF THE INVENTION

It is an object of the invention to provide an LED lamp that can be easy fabricated at a low production cost.

It is a further object of the invention to provide an LED lamp apparatus equipped with the LED lamp.

(1) According to one aspect of the invention, an LED lamp comprises:
a sealing member;
first, second and third leads, a part of the first, second and third leads being surrounded by the sealing member;
an LED chip mounted on the first lead: and
a wire disposed connecting the second lead and the LED chip,
wherein the third lead is connected through an electrical path to the first or second lead.

In the above invention (1), the following modifications and changes can be made.

(i) A terminal is formed by an end of the third lead and an end of the first or second lead not connected through the electrical path to the third lead.

(ii) The electrical path comprises a resistor element, and the resistor element is disposed connecting the first or second lead and the third lead.

(iii) The first lead comprises its end surrounded by the sealing member and disposed at a center of the LED lamp.

(2) According to another aspect of the invention, an LED lamp apparatus comprises:
the LED lamp as defined in the invention (1); and
a case portion that houses the first, second and third leads,
wherein the terminal protrudes from the case portion.

In the above invention (2), the following modifications and changes can be made.

(iv) The first, second and third leads form a circuit portion inside the case portion.

<Advantages of the Invention>

In the invention, the LED lamp is provided with the three leads so that the circuit portion can be formed by the three leads. Especially, the third lead is not directly connected to the LED chip so that freedom in design of the circuit portion can be enhanced. Further, since the circuit portion is formed only by the three leads, it is not needed to use a board or metal plate normally used to form the circuit portion. Thus, the fabrication can be easy conducted and the LED lamp apparatus can be offered at a low cost.

### BRIEF DESCRIPTION OF THE DRAWINGS

The preferred embodiments according to the invention will be explained below referring to the drawings, wherein:

FIG. 1 is a schematic disassembled view showing the conventional LED lamp apparatus;

FIG. 2 is a schematic front view showing an LED lamp in a first preferred embodiment according to the invention;

FIG. 3 is a top view showing the LED lamp in FIG. 1;

FIG. 4 is a circuit diagram showing a circuit composition of the LED lamp;

FIG. 5 is a schematic front view showing a method of making the LED lamp;

FIG. 6A is a top view showing an LED lamp apparatus in a preferred embodiment according to the invention;

FIG. 6B is a cross sectional view showing the LED lamp apparatus in FIG. 6A;

FIG. 7 is a schematic front view showing an LED lamp in a second preferred embodiment according to the invention: and

FIG. 8 is a circuit diagram showing a circuit composition of the LED lamp in FIG. 7.

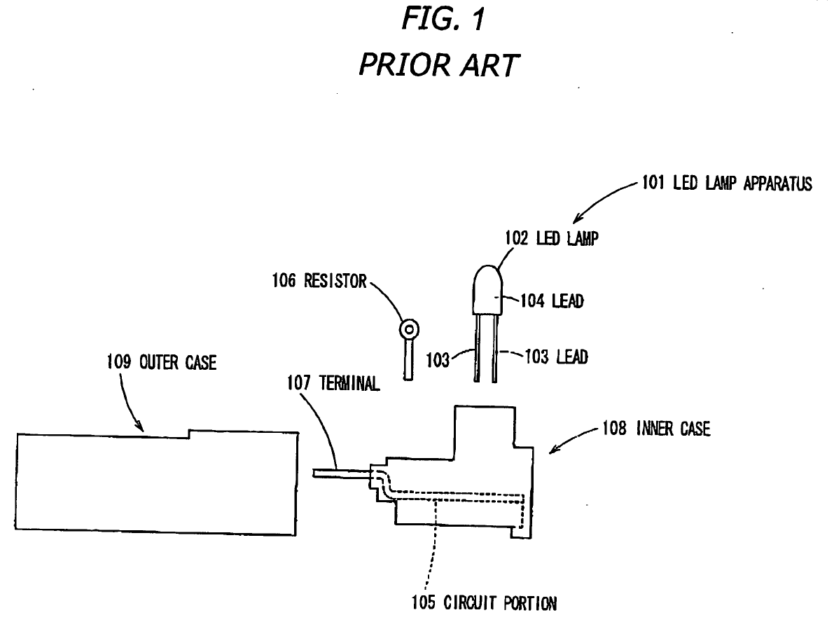

### DETAILED DESCRIPTION OF THE PREFERRED EMBODIMENTS

Elements of the invention will be explained below.

LED Chip

The type of an LED chip used in the invention is not limited. The LED chip may be of a type with electrodes formed on the top and bottom thereof, a type (face-up) with both electrodes formed on the top thereof, and a flip-chip type with both electrodes formed on the bottom thereof. Further, the LED chip may be mounted directly on a cup portion of a first lead, and a submount may be interposed therebetween.

The emission color of the LED chip can be arbitrarily optioned. Although a blue LED chip is used in the in the embodiments below, the other LED chips with a visible-region emission wavelength such as white, red, orange and green can be used. Further, LED chips of different kind and/or emission color can be combined.

Sealing Usher

A sealing member is used to cover the LED chip, and it can be formed of a transparent material which can be suitably optioned according to use and object. The sealing member includes suitably a lens-shaped portion in order to focus light emitted from the LED chip.

The sealing member can have a phosphor mixed therein. Alternatively, a layer including the phosphor can be formed on the surface of the sealing member.

The kind of the phosphor can be suitably optioned in combination of the emission light of the LED chip according to use and object of the LED lamp. For example, with a blue LED chip, the emission color of the LED lamp can be white by using a phosphor to generate a yellow light by the blue light. Also, with a ultraviolet LED chip, the fluorescent LED lamp can be made by using a phosphor to generate fluorescence by the ultraviolet light.

Read

At least three leads are used in the invention. The base portion of the leads is surrounded by the sealing member. Thereby, the respective leads can be in mechanically stable state supported by the sealing member although disposed like a cantilever. The leads can be arbitrarily optioned in shape and material if only they are electrically conductive. The leads are preferably formed of a metal plate in consideration of the mass productivity and production cost.

The first lead is provided with the LED chip mounted thereon. Since it is desired to dispose the LED chip as a light source on the optical axis (center) of the LED lamp, it is preferred that the base portion of the first lead is also disposed at the center of the LED lamp.

The second lead is provided with a bonding area (bonding pad) for a wire, which is disposed connecting the bonding area and the LED chip. Thereby, power can be supplied to the LED chip.

The third lead is not connected directly to the LED chip. In other words, the third lead is electrically separated from the LED chip. By using the third lead, a circuit portion is formed with the first and second leads connected to the LED chip. The third lead may be composed of plural leads. By using the plural third leads, freedom in circuit design can be further enhanced.

The base portion of the at least three leads surrounded by the sealing member is preferably disposed on one plane. This is because the base portion as an insert can be set when the sealing member is molded using the insert. Also, when the three leads are formed by punching one metal plate, they can be directly used as an insert while being retained with a fixing tape after being punched.

As a form of the circuit portion, when the third lead is connected through an electrical path to the first or second lead, terminals can be formed by the end of the third lead and the end of the lead not connected through the path to the third lead.

Thus, a part of the terminals is assigned to the third lead not connected to the LED chip, so that the circuit can be formed without connecting the third lead directly to the LED chip.

For example, as described in the embodiments later, the first lead with the LED mounted thereon is connected with the third lead such that it is not used as the terminal and its end forms a free end (i.e., being not connected to other connector). Thereby, thermal influence from a resistor element to the LED chip mounted on the first lead can be prevented.

The resistor element is most needed in elements composing the LED circuit portion, and is disposed in series to the LED chip. To dispose the resistor element in series, the resistor element is disposed connecting the first lead with the LED chip mounted thereon and the third lead separated from the LED chip so that the LED chip is connected through the first lead, the resistor element to the third lead to use the third lead as an anode (i.e., positive electrode) terminal.

It is preferred that a Zener diode is disposed connecting the first lead and the second lead and in parallel to the LED chip, and that the second lead is used as a cathode (negative electrode) terminal.

The circuit portion composed of the first to third leads can be arbitrarily designed according to use and object of the LED lamp apparatus. Although in the embodiments the free end of the third lead is used as a component of the terminals, the terminals may be composed by using the free end of the first and second leads.

A case portion can be arbitrarily optioned in shape and material according to use and object of the LED lamp apparatus. It is preferred that it is formed of a plastic molding in consideration of the mass productivity, weight reduction, production cost.

The preferred embodiments of the invention will be described below.

### First Embodiment

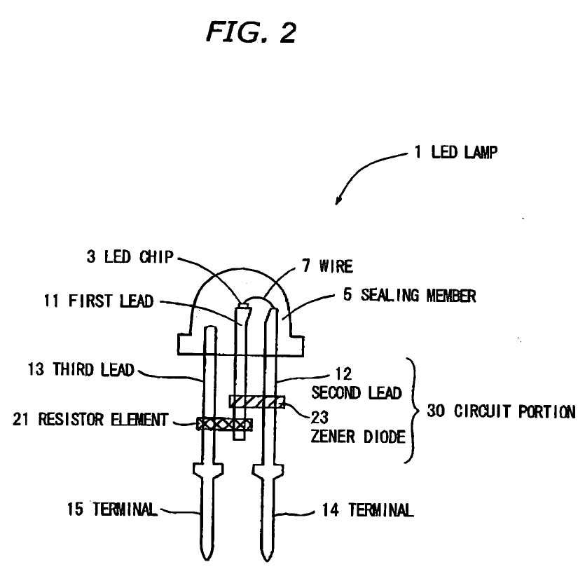

FIG. 2 is a schematic front view showing an LED lamp in the first preferred embodiment according to the invention.

The LED lamp 1 of the embodiment comprises an LED chip 3, a sealing member 5, a first lead 11, a second lead 12 and a third lead.

The LED chip 3 is a blue LED made of group III nitride-based compound semiconductor. The sealing member 5 is made of a transparent epoxy resin and molded into a bullet-shape.

The LED chip 3 is mounted on the top base of the first lead 11. The negative-electrode bonding pad of the LED chip 3 is electrically connected through a wire 7 to the top of the second lead 12. The first lead 11 is disposed on the central axis (optical axis) of the LED lamp 1, so that the LED chip 3 is also disposed on the central axis of the LED lamp 1.

The third lead 13 is not connected directly to the LED chip 3. In this embodiment, the height of the third lead 13 is set to be lower than the leads 11, 12. However, the embedding depth of the leads 11 to 13 into the sealing member 5 is not limited if only they are mechanically stable.

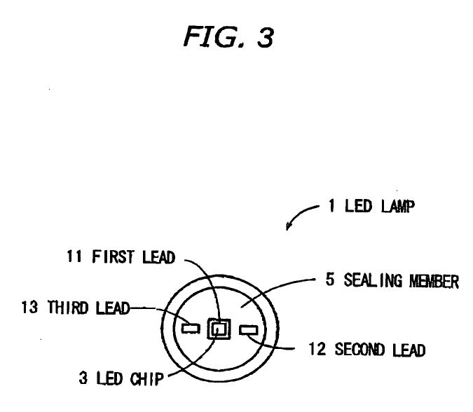

It is preferred that the leads 11 to 13 are, as shown in FIG. 3, disposed in a row (and on one plane).

Alternatively, the leads 11-13 may be disposed at apexes of a virtual triangle.

The number of the leads is not limited to three, and can be more than three.

A resistor element 21 is disposed connecting the first lead 11 and the third lead 13. The resistor element 21 is used to control the amount of current supplied to the LED chip 3, and can be arbitrarily optioned according to use and object of the LED chip 3. A Zener diode 23 is disposed connecting the first lead 11 and the second lead 12. The Zener diode 23 is used to protect the LED chip 3 from reverse voltage and forward overvoltage, and may be built in a submount to mount the LED chip 3 thereon.

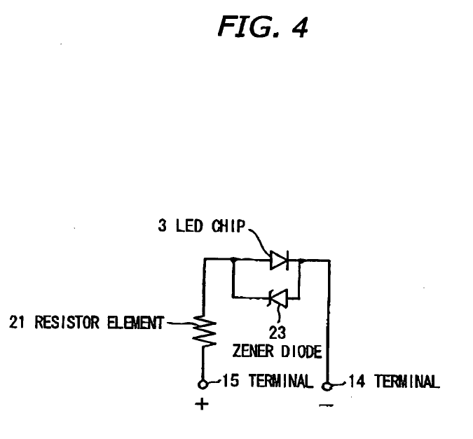

FIG. 4 is a circuit diagram showing a circuit composition of the LED lamp.

In this embodiment, as shown in FIG. 2, a circuit portion 30 is formed by extending the leads 11, 12 and 13 and disposing the resistor element etc. therebetween.

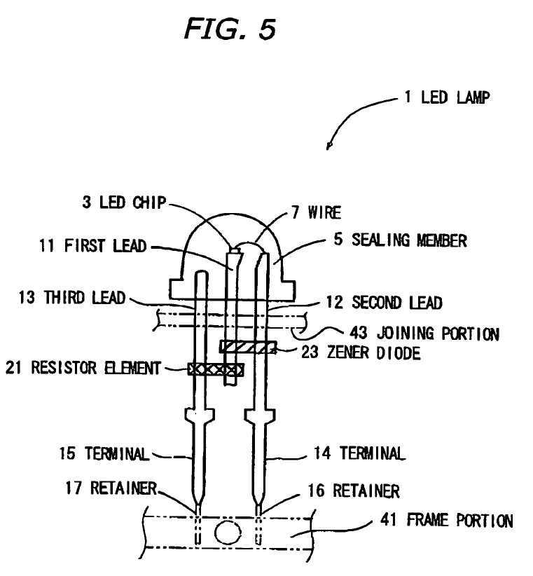

The first to third leads 11, 12, 13 are formed by punching a metal plate with electrical conductivity. At that time, as shown in FIG. 5, retainers 16, 17 are formed at the tip of the terminals 14, 15. The retainer 16, 17 are continuously formed with a frame portion 41 of the metal plate as a base material of the leads 11, 12, 13. Also, the base end portion of the leads 11, 12, 13 is continuously formed with a joining portion 43 which is a part of the metal plate.

The LED chip 3 is mounted on the first lead 11 while the leads 11, 12, 13 are joined. Then, the bonding wire 7 is disposed connecting the LED chip 3 and the second lead 12. These are placed as an insert in a bullet-shaped cavity, the material of the sealing member 5 is injected into the cavity. Then, the resistor element 21 is disposed connecting the first lead 11 and the third lead 13, and the Zener diode 23 is disposed connecting the first lead 11 and the second lead 12.

Finally, the retainers 16, 17 and the joining portion 43 are removed by punching to obtain the LED lamp 1 as shown in FIG. 2.

Alternatively, the leads 11, 12, 13 can be fixed at the base end portion thereof by using a fixing tape instead of the joining portion 43 continuously formed the leads 11, 12, 13.

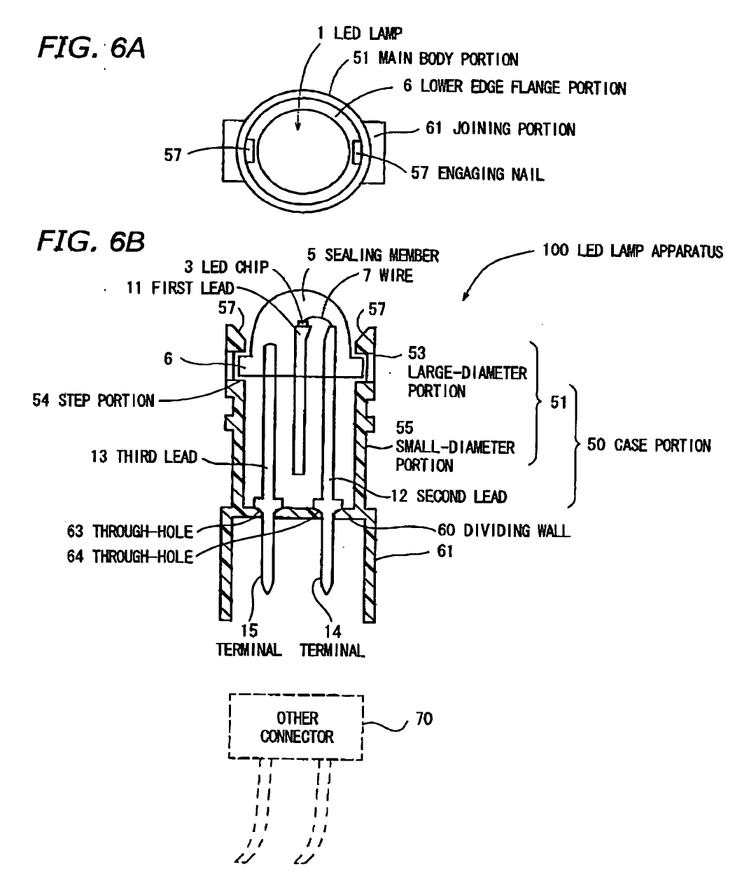

The LED lamp 1 thus obtained is set in a case portion 50 as shown in FIG. 6. The LED lamp: 1 and the case portion 50 compose an LED lamp apparatus 100.

The case portion 50 comprises a cylindrical main body portion 51 and a joining portion 61. The main body portion 51 comprises a large-diameter portion 53 at its opening side and a small-diameter portion 55 extended therefrom, between which a step portion 54 is formed. A lower-edge flange portion 6 of the sealing member 5 is mounted on the step portion 54. The large-diameter portion 53 is provided with an engaging nail 57 on its inside surface so that the lower-edge flange portion 6 of the sealing member 5 is engaged between the engaging nail 57 and the step portion 64.

The main body portion 51 and the joining portion 61 are integrated through a dividing wall 60. The dividing wall 60 is provided with through-holes 63, 64, through which the terminals 14, 15 are inserted and protrudes from the main body portion 51.

70 is other connector which is connected to, e.g., an electrical system of a vehicle. The terminals 14, 15 protruding from the main body portion 51 are inserted into the connector 70.

### Second Embodiment

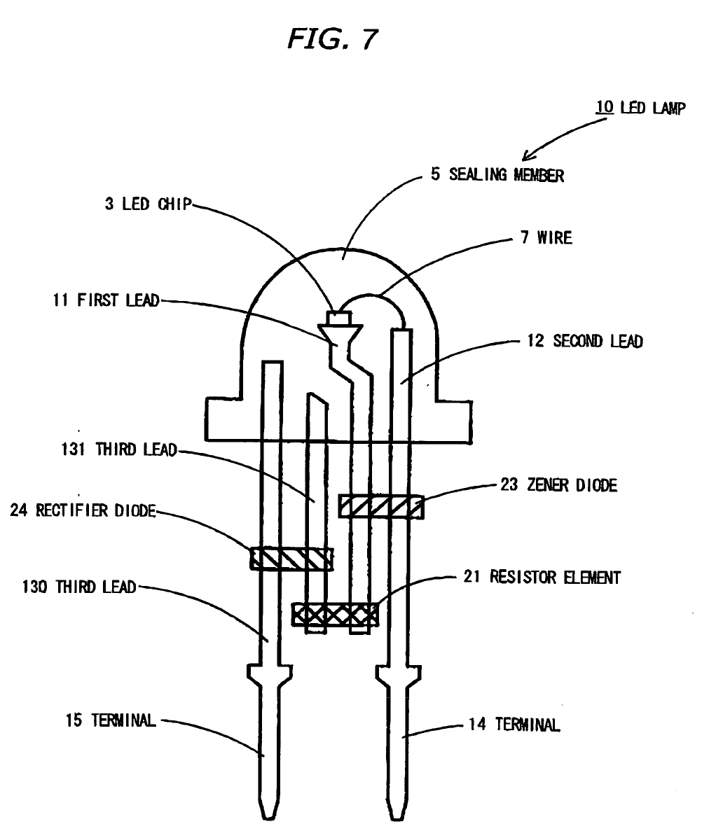

FIG. 7 is a schematic front view showing an LED lamp 10 in the second preferred embodiment according to the invention. Like components are indicated by the same numerals as used for the LED lamp 1 and its explanation is omitted below.

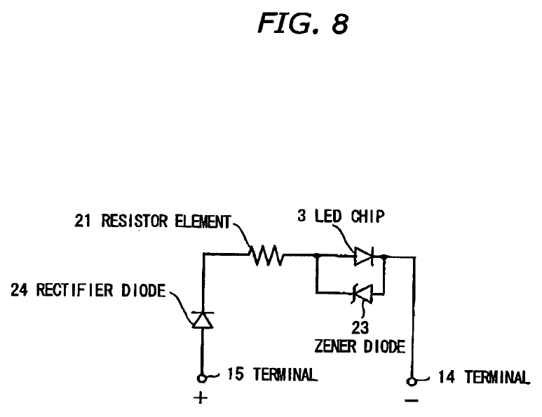

FIG. 8 is a circuit diagram showing a circuit composition of the LED lamp in FIG. 7.

The LED lamp 10 comprises two leads 130, 131 as the third lead, in addition to the LED chip 3, the sealing member 5, the first lead 11 and the second lead 12. The first to third leads 11, 12, 130 and 131 are disposed in a row (on one plane). A rectifier diode 24 is disposed connecting the third leads 130 and 131. The rectifier diode 24 is used to protect the LED chip 3 from reverse current. By the rectifier diode 24, the LED chip 3 can be protected from breakage when the LED lamp 10 is erroneously connected in reverse. The end of the third lead 130 not sealed with the sealing member 5 forms the anode terminal 15. On the other hand, the end of the third lead 131 not sealed with the sealing member 5 is shorter than the anode terminal 15 and forms a free end. Similarly to the LED lamp 10, the Zener diode 23 is disposed connecting the third lead 131 and the first lead 11. The LED lamp 10 is fabricated to form the circuit as shown in FIG. 8. The first to third leads 11, 12, 130 and 131 are formed by punching a metal plate with electrical conductivity as conducted in the LED lamp 1.

In the LED lamp 10, the rectifier diode 24 is disposed connecting the two third leads. Thus, as the number of third leads used-increases, the number of elements disposed therebetween can be increased. Therefore, freedom in circuit design can be further enhanced. With the LED lamp 10, an LED lamp apparatus can be also formed using the case portion 50 as in the LED lamp 1.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An LED lamp, comprising:
a sealing member;
first, second and third leads, a part of the first, second and third leads being surrounded by the sealing member;
an LED chip mounted on the first lead;
a wire disposed connecting the second lead and the LED chip,
wherein the third lead is connected through an electrical path to the first or second lead.

2. The LED lamp according to claim 1, wherein:
a terminal is formed by an end of the third lead and an end of the first or second lead not connected through the electrical path to the third lead.

3. The LED lamp according to claim 1, wherein:
the electrical path comprises a resistor element, and
the resistor element is disposed connecting the first or second lead and the third lead.

4. The LED lamp according to claim 1, wherein:
the first lead comprises its end surrounded by the sealing member and disposed at a center of the LED lamp.

5. An LED lamp apparatus, comprising:
the LED lamp as defined in claim 2; and
a case portion that houses the firsts second and third leads,
wherein the terminal protrudes from the case portion.

6. The LED lamp apparatus according to claim 5, wherein: the first, second and third leads form a circuit portion inside the case portion.
